(19) United States
(12) Patent Application Publication
(10) Pub. No.: US 2007/0128741 A1
(43) Pub. Date: Jun. 7, 2007

(54) System and method for using a split capacitive barrier edge sensor

(76) Inventor: James J. Fitzgibbon, Batavia, IL (US)

Correspondence Address: FITCH EVEN TABIN AND FLANNERY, 120 SOUTH LA SALLE STREET, SUITE 1600, CHICAGO, IL, 60603-3406, US

(21) Appl. No.: 11/295,224

(22) Filed: Dec. 6, 2005

(51) Int. Cl. H01L 21/66; H01L 23/58; H01L 21/8242

(52) U.S. Cl. 438/17; 438/240; 257/48

(57) ABSTRACT

A plurality of conductive members is disposed on an edge of a moveable barrier. The edge has a width and each of the conductive members is disposed along a portion of the width. A controller is coupled to each of the plurality of conductive members and is programmed to determine whether an obstruction exists within a path of movement of the barrier by analyzing a first capacitance sensed by a first of the plurality of conductive members and ground and a second capacitance sensed by a second of the plurality of conductive members and ground.

### FIELD OF THE INVENTION

The field of the invention generally relates to methods and devices for controlling movable barrier operators. More specifically, the invention relates to detecting obstructions in the pathways of moveable barriers.

### BACKGROUND

Barrier movement operators are automated systems which are used to move a barrier with respect to an opening. Examples of barriers to be moved include garage doors, gates, fire doors and rolling shutters. A number of barrier movement operators have been sold over the years most of which include a head unit containing a motor connected to a transmission. The transmission, which may include, for example, a belt drive, a chain drive, a screw drive or extendible arm is then coupled to the barrier for opening and closing.

Such barrier movement operators also typically include a wall control unit, which is connected to send signals to the head unit thereby causing the head unit to open and close the barrier. In addition, these operators often include a receiver unit at the head unit to receive wireless transmissions from a hand-held code transmitter or from a keypad transmitter, which may be affixed to the outside of the area closed by the barrier or other structure.

Obstructions may exist or may enter the pathway of the moveable barrier. Previous systems have allowed the barrier operator systems to determine if an obstruction has been encountered and to either stop or reverse the direction of the travel of the barrier once this determination has been made. For instance, some previous systems measured the force applied to the barrier by the motor. The systems then compared the measured force to an expected value plus a fixed cushion value. If the comparison indicated that the measurement value exceeded the expected value plus the cushion value (together, a threshold value), then the downward barrier movement was reversed. These systems typically determined the force by measuring the barrier speed or current in the motor and then calculated the force using these measurements.

In some previous systems, capacitive sensor arrangements were used to detect the obstruction in the pathway of the door by detecting the capacitance between a conductive element and the ground. However, in these previous systems, the sensed capacitance between a conductive element and the ground increased above a threshold as the sensor approached the ground thereby indicating that an “obstruction” existed. Consequently, as the door neared the ground, the capacitance reading would have to be adjusted or discarded because the reading would indicate an obstruction existed, when, in fact, the ground was the “obstruction” being detected. Thus, these previous systems could not be used to detect an obstruction unless the readings were sufficiently adjusted to take into account the detection of the ground or other reference.

Sensors may also become damaged through use or due to other circumstances. When the sensors become damaged, then operational malfunctions can occur such that obstructions are not detected and the barrier may, as a result, crash into the obstruction. Previous systems could not easily detect when the sensors were damaged or depended upon a manual examination of the sensors to determine if damage existed. Consequently, previous approaches proved inadequate in detecting damage and/or were inconvenient for users to determine when damage existed.

### SUMMARY

A system and method for detecting obstructions in the door are described. The system and method use a plurality of capacitive sensors to determine whether obstructions are present in the path of a moveable barrier. In addition, the approaches described herein allow the easy and automatic determination of whether a sensor has become damaged.

In many of these embodiments, a plurality of conductive members are disposed on an edge of a moveable barrier. The edge has a width and each of the conductive members is disposed along a portion of the width. A controller is coupled to each of the plurality of conductive members and is programmed to determine whether an obstruction exists within a path of movement of the barrier by analyzing a first capacitance (sensed between a first of the plurality of conductive members and ground) and a second capacitance (sensed by a second of the plurality of conductive members and ground). Moreover, the controller may determine a relationship between a capacitance the first capacitance and the second capacitance. In one example, the relationship is a ratio between the first capacitance and the second capacitance.

Determination of whether an obstruction exists in the path of the door may be based upon a variety of factors. For example, the existence of an obstruction may be determined based upon an analysis of the first capacitance, the second capacitance, and/or the relationship. In another example, the controller may be programmed to determine a sensitivity to an obstruction by analyzing an average capacitance sensed by of at least two of the conductive members and ground. This sensitivity may be updated periodically.

The controller may also be programmed to determine whether one of the conductive members has been damaged. Whether damage has actually occurred may be based upon an analysis of the first capacitance, the second capacitance, and/or the relationship.

The various conductive elements may be positioned in a variety of arrangements. For example, a portion of the first conductive element may be position along a first section of the edge of the door and this section may not include a portion of the second conductive element. Further, a second section of the width of the door may include a portion of the second conductive element but not a portion the first conductive element.

In others of these embodiments, the controller may be programmed to create a map of the sensed capacitances of the conductive elements at various positions of the barrier and to store the map in memory. The memory map may then be used to determine when an obstruction has been reached.

Thus, approaches are described herein that determine whether an obstruction exists in the path of a moveable barrier based upon the measurements of capacitive sensors. Damage to the sensors can also be determined based upon the sensor readings. The approaches described herein are easy to use, accurate, and require little or no intervention from human users of the system.

### BRIEF DESCRIPTION OF THE DRAWINGS

FIG. 1 is a diagram of a system for detecting an obstruction and/or sensor damage according to the present invention;

FIG. 2 is a diagram of a system for detecting an obstruction and/or sensor damage according to the present invention; and

FIG. 3 is a diagram of a system for detecting an obstruction and/or sensor damage according to the present invention;

FIG. 4 is a diagram of a mapping according to the present invention; and

FIG. 5 is a flowchart of one approach for determining whether an obstruction exists and whether sensor damage exists according to the present invention.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of various embodiments of the present invention. Also, common but well understood elements that are useful in a commercially feasible embodiment are often not depicted in order to facilitate a less obstructed view of the various embodiments of the present invention.

### DESCRIPTION

For illustrative purposes, the following description refers to a moveable barrier that is a garage door. However, it will be understood by those skilled in the art that the moveable barrier may not only be a garage door but may be any type of barrier such as a fire door, shutter, window, gate. Other examples of barriers are possible.

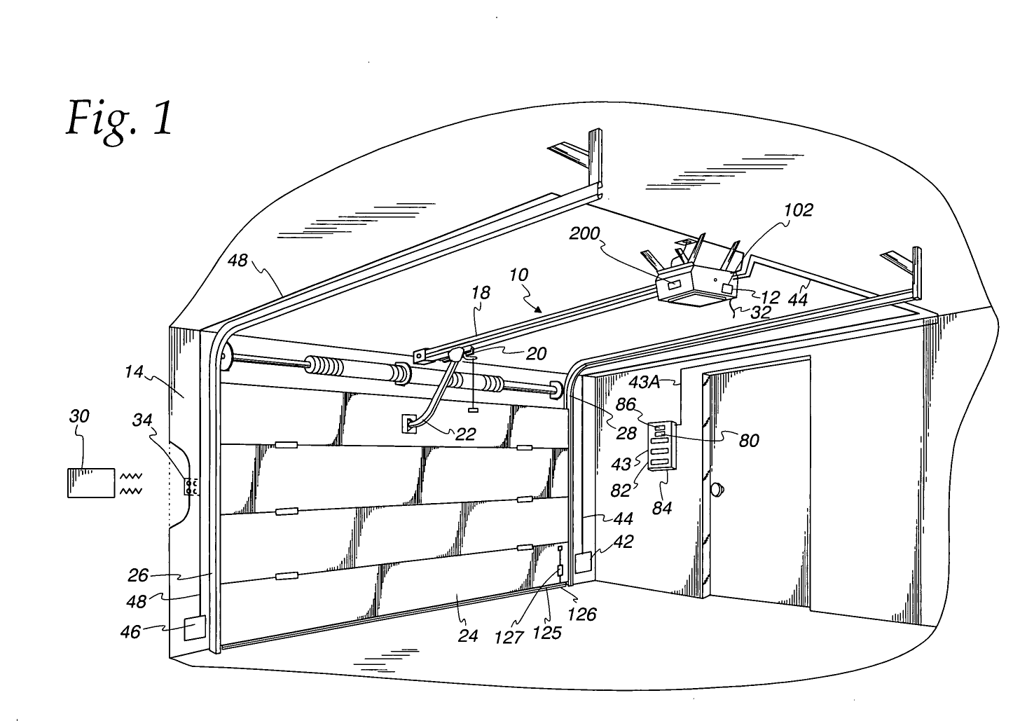

Referring now to the drawings and especially to FIG. 1, a movable barrier operator, which is a garage door operator, is generally shown therein and includes a head unit 12 mounted within a garage 14. More specifically, the head unit 12 is mounted to the ceiling of the garage 14 and includes a rail 18 extending there from with a releasable trolley 20 attached having an arm 22 extending to a multiple paneled garage door 24 positioned for movement along a pair of door rails 26 and 28. The system includes a hand-held transmitter unit 30 adapted to send signals to an antenna 32 positioned on the head unit 12 as will appear hereinafter. An external control pad 34 is positioned on the outside of the garage having a plurality of buttons thereon and communicates via radio frequency transmission with the antenna 32 of the head unit 12. An optical emitter 42 is connected via a power and signal line 44 to the head unit. An optical detector 46 is connected via a wire 48 to the head unit 12. The head unit 12 also includes a receiver unit 102. The receiver unit 102 receives a wireless signal, which is used to actuate the garage door opener.

The door 24 has a plurality of conductive members 125 attached. The conductive members 125 may be a wire, rod or any element or combination of elements having conductivity. In one approach, the conductive members 125 are enclosed and held by a holder 126. Alternatively, the conductive members may be coupled directly to the door 24. The conductive members 125 are coupled to a sensor circuit 127. The sensor circuit 127 transmits indications of obstructions to the head unit 12. If an obstruction is detected, the head unit 12 can reverse direction of the travel of the door 24.

As the holder 126 enclosing the conductive members 125 approaches the ground, the conductive members 125 are lifted by the holder 126. By analyzing the capacitances sensed between the conductive members and ground, it may be determined if an obstruction exists in the path of the barrier 24. Moreover, a relationship or relationships may be determined between the measured capacitances. In one example, the relationships are ratios between different ones of the measured capacitances. Other examples of relationships are possible.

Determination of whether an obstruction exists in the path of the barrier 24 may be based upon a variety of factors. For example, the existence of an obstruction may be determined based upon an analysis of the capacitances and/or the relationship or relationships. In another example, an average capacitance sensed by of at least two of the conductive members 125 and ground may be analyzed to determine whether an obstruction exists.

It may also be determined whether any of the conductive members 125 have been damaged. Whether damage has actually occurred may be based upon an analysis of the first capacitance, the second capacitance, and/or the relationship.

The head unit 12 has the wall control panel 43 connected to it via a wire or line 43A. The wall control panel 43 includes a decoder, which decodes closures of a lock switch 80, a learn switch 82 and a command switch 84 in the wall circuit. The wall control panel 43 also includes a light emitting diode 86 connected by a resistor to the line 43 and to ground to indicate that the wall control panel 43 is energized by the head unit 12. Switch closures are decoded by the decoder, which sends signals along lines 43A to a control unit 200 coupled via control lines to an electric motor positioned within the head unit 12. In other embodiments, analog signals may be exchanged between wall control 43 and head unit

The wall control panel 43 is placed in a position such that an operator can observe the garage door 24. In this respect, the control panel 43 may be in a fixed position. However, it may also be moveable as well. The wall control panel 43 may also use a wirelessly coupled connection to the head unit 12 instead of the wire 43A. If an obstruction is detected, the direction of travel of the door 24 may be reversed by the control unit 200.

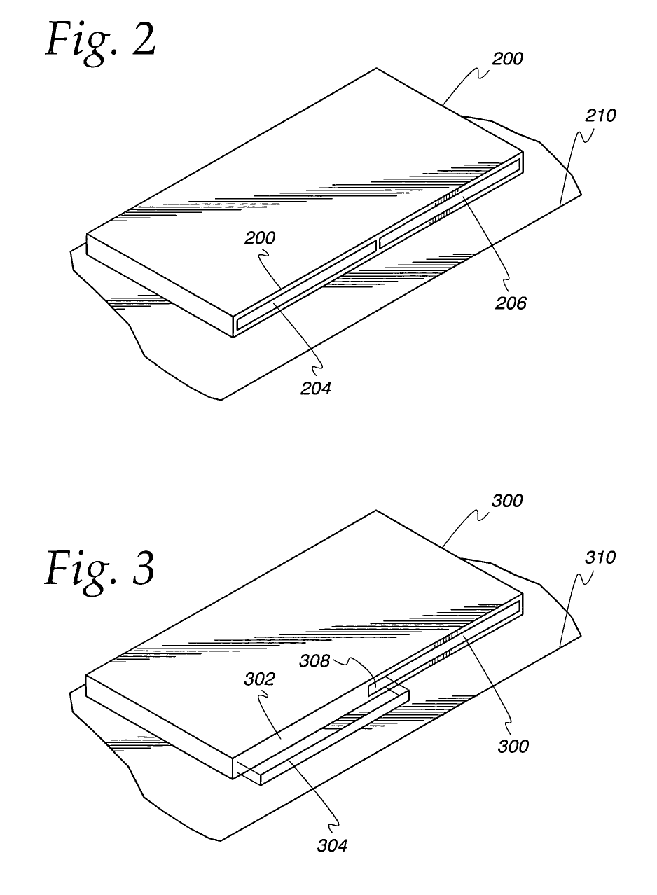

Referring now to FIG. 2, an example of a moveable barrier 200 with a plurality of conductive members disposed along an edge 202 of the barrier 200 is described. Along the edge 202 of the barrier 200 are two conductive members 204 and 206. The capacitance as measured at conductive member 204 has a value of Ca and the capacitance as measured at the conductive member 206 has a value of Cb. The two conductive members 204 and 206 do not overlap and are attached to the edge 202. Alternatively, the conductive members 204 and 206 may be held by a holder and the holder may move upwardly as the ground 210 is approached. A controller in the head unit may calculate a relationship between Ca and Cb such as a ratio and determine the presence of obstructions and/or sensor damage. Alternatively, a controller or control circuit at a location other than at the head unit may perform obstruction and/or damage existence assessments.

In FIG. 2, only two conductive elements are shown. However, it will be understood that any number of conductive elements may be used. The same relative measurement can be made with any number of potential combinations. For example, in one approach, all capacitances for all the sections are measured to ensure that the value is the same within some tolerance.

When no obstruction exists, as the barrier approaches the ground 210, the absolute capacitance increases, but Ca and Cb are increase at approximately the same rate allowing the ratio of Ca to Cb to remain constant. However, when an obstruction is present, the obstruction increases the capacitance as measured at the conductive elements 204 and/or 206. The relationship of Ca to Cb also changes.

Determination of whether an obstruction exists in the path of the barrier 200 may be based upon the values of Ca and Cb and/or the determined relationship. Specifically, whenever the ratio exceeds a threshold value, an obstruction may be determined to exist.

In another example, the average capacitance sensed by the two conductive members 202 and 204 and ground 210 may be calculated and analyzed in order to determine whether an obstruction exists. Specifically, whenever the average capacitance at a particular point in the barrier's movement exceeds an expected value by more than a tolerance, an obstruction may be determined to exist. A memory map may be used for this purpose as described elsewhere in this specification. In another example, the actual measured capacitances at particular points in the movement of the barrier may be compared to expected values in order to determine whether an obstruction is present. Again, a memory map may be used to facilitate this approach.

The ratio of Ca to Cb may be used to detect damage that has occurred to the capacitive elements 204 or 206. Since a section of Ca or Cb is removed, altered, or disabled by the damage, the ratio of Ca to Cb will change. Consequently, the existence of damage may be determined by evaluating changes in the ratio and comparing these changes to the expected change for a damaged sensor.

Referring now to FIG. 3, another example of a moveable barrier 300 with a plurality of conductive members along the edge 302 of the barrier 300 is described. Along the edge of the barrier are two conductive members 304 and 306. The two conductive members 304 and 306 overlap and are coupled together at a coupling region 308. The capacitance as measured at conductive member 304 has a value of Ca and the capacitance as measured at the conductive member 306 has a value of Cb. The two conductive members 304 and 306 are connected to the edge 302 such that the member 304 is in front of the member 306. Alternatively, the members may be held in a holder as described above.

The coupling region 308 is an area in common for each of the sensors. If a signal is applied to the first conductive member 304, this signal can be used to detect the conductive member 306 (and vice versa). The mutual coupling can also be used in order to detect damage to one of the conductive members 304 or 306. If the mutual coupling disappears or is diminished and the door is not on the ground 310, then one of the conductive members 304 or 306 is likely damaged.

Determination of whether an obstruction exists in the path of the barrier 300 may be based upon a variety of factors. For example, the existence of an obstruction may be determined based upon an analysis of the capacitances and/or the relationship or relationships. In another example, an average capacitance (or the actual capacitances) sensed by the two conductive members 302 and 304 and ground may be compared to expected values for particular points in the movement of the barrier to determine whether an obstruction exists. A memory map may be used for this purpose as described elsewhere in this specification.

In FIG. 3, only two overlapping conductive elements are shown. However, it will be understood that any number of conductive elements may be used and these different elements may have more than one overlapping area. In this case, each overlapping area may be analyzed as described above in order to determine whether damage exists.

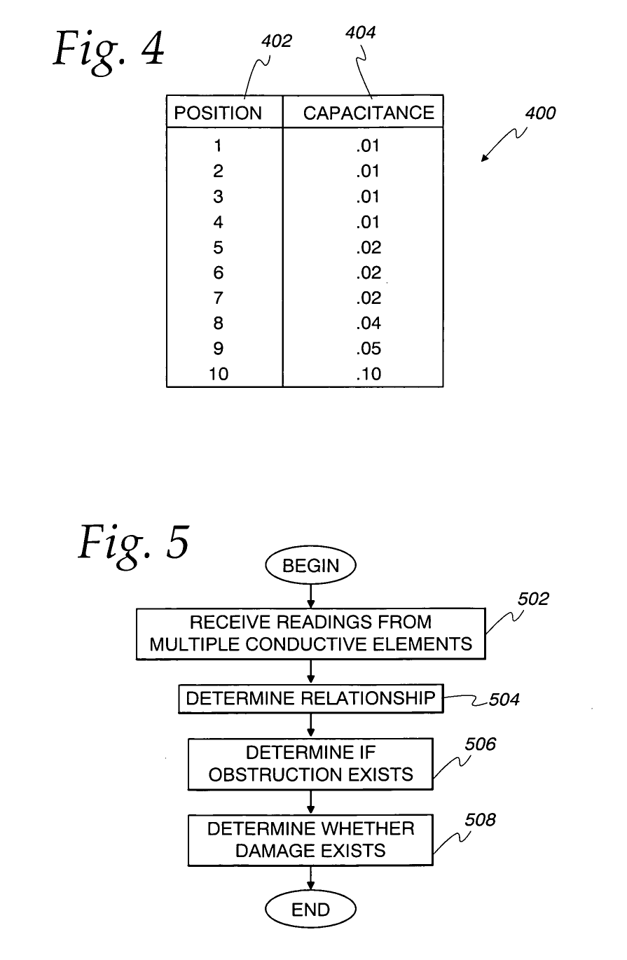

Referring now to FIG. 4, one example of a memory map 400 is described. The memory map 400 includes a position column 402 and a capacitance column 404. The capacitance in the capacitance column 404 corresponds to a position in the position column 402. Consequently, it can be determined from a measured capacitance where the barrier is located (e.g., how far above the ground the barrier is located). In this example, the capacitance is the average capacitance of all the conductive members. Alternatively, each capacitance for each of the plurality of conductive members may be stored in a separate column.

In one approach, a controller may record the capacitance measured in the memory map 400. For example, at position 1, the capacitance may be 0.01 micro farads. At position 2, the capacitance may be 0.1 micro farads. The memory map may be used to determine the position of the door based upon a measured capacitance. Although shown with 10 positional values, it will be understood that any number of values may be stored in the table.

The memory map 400 may be used to determine if an obstruction exists. For example, the measured capacitances (or average capacitance of all the conductive members) may be compared to the expected capacitance at a certain point in the movement of the barrier. If the measured value deviates from the expected value by more than a threshold tolerance, it can be determined that an obstruction exists in the path of the barrier.

Referring now to FIG. 5, one example of an approach for determining whether an obstruction is present in the path of a barrier and whether damage exists to a sensor on the barrier is described. In this example, two conductive elements are used. However, as described previously, any number of conductive elements may also be used. At step 502, capacitance measurements from multiple conductive members are received. At step 504, a relationship between these measurements is determined. In one example, a ratio of two measured capacitances (or ratios between multiple capacitances when more than two elements are used) is determined.

At step 506, using the relationship and/or the readings, it is determined if an obstruction exists. For example, if the relationship exceeds a predetermined value by more than a predetermined tolerance, it may be determined that an obstruction exists. In another example, if the average value of the expected capacitance at a particular point is exceeded by a threshold value plus a predetermine tolerance, an obstruction may be determined to exist. A memory map may be used for this purpose as described elsewhere in this specification.

At step 508, using the relationship and/or readings, it is determined if any of the conductive members is damaged. For instance, if mutual coupling exists, then it may be determined if the mutual coupling has disappeared or has been significantly reduced. In another example, if the relationship changes above a certain value, then damage to a sensor may be determined.

While there has been illustrated and described particular embodiments of the present invention, it will be appreciated that numerous changes and modifications will occur to those skilled in the art, and it is intended in the appended claims to cover all those changes and modifications which fall within the true scope of the present invention.

What is claimed is:

1. A obstruction sensing system for a moveable barrier comprising:
a plurality of conductive members disposed on an edge of a moveable barrier, wherein the edge has a width and each of the conductive members is disposed along a portion of the width; and
a controller coupled to each of the plurality of conductive members, the controller programmed to determine whether an obstruction exists within a path of movement of the barrier by analyzing a first capacitance sensed by a first of the plurality of conductive members and ground and a second capacitance sensed by a second of the plurality of conductive members and ground.

2. The system of claim 1 wherein the controller is programmed to determine whether one of the plurality of conductive members is damaged based upon analyzing the first capacitance and the second capacitance.

3. The system of claim 1 wherein the controller is programmed to determine a relationship between a capacitance between the first capacitance and the second capacitance and to determine whether the obstruction exists in the path of the door based upon the first capacitance, the second capacitance, and the relationship.

4. The system of claim 3 wherein the controller is programmed to determine whether one of the plurality of conductive members is damaged based upon analyzing the first capacitance, the second capacitance, and the relationship.

5. The system of claim 4 wherein the relationship comprises a ratio.

6. The system of claim 1 wherein the width of the edge comprises a first section and a second section, wherein the first section includes a portion of the first conductive element and not a portion of the second conductive element, and wherein the second section includes a portion of the second conductive element and not a portion the first conductive element.

7. The system of claim 1 wherein the first and second conductive elements are separate and distinct from each other.

8. The system of claim 1 wherein the first and second conductive elements are separated by a high impedance.

9. The system of claim 1 wherein the controller is programmed to determine a sensitivity to an obstruction by analyzing an average capacitance sensed by of at least two of the plurality of conductive members and ground.

10. The system of claim 9 wherein the controller is programmed to update the sensitivity periodically.

11. The system of claim 1 wherein the controller is programmed to create a map of sensed capacitances versus positions of the barrier and to store the map in memory.

12. A system for determining damage to conductive members disposed on a barrier comprising:
a plurality of conductive members disposed on an edge of a moveable barrier, wherein the edge has a width and each of the conductive members is disposed along a portion of the width; and
a controller coupled to each of the plurality of conductive members, the controller programmed to determine whether damage exists to one of the conductive members by analyzing a first capacitance sensed by a first of the plurality of conductive members and ground and a second capacitance sensed by a second of the plurality of members and ground.

13. The system of claim 12 wherein the controller is programmed to determine a relationship between the first capacitance and the second capacitance and to determine whether damage exists based upon the first capacitance, the second capacitance, and the relationship.

14. The system of claim 12 wherein the relationship comprises a ratio.

15. The system of claim 12 wherein the width of the edge comprises a first section and a second section, wherein the first section includes a portion of the first conductive element and not a portion of the second conductive element, and wherein the second section includes a portion of the second conductive element and not a portion the first conductive element.

16. The system of claim 12 wherein the controller is programmed to determine a sensitivity to an obstruction by analyzing an average capacitance sensed by of at least two of the plurality of conductive members and ground.

17. The system of claim 16 wherein the controller is programmed to update the sensitivity periodically.

18. The system of claim 12 wherein the controller is programmed to create a map of sensed capacitances versus positions of the barrier and to store the map in memory.

19. A method for determining whether an obstruction exists in a path of a moveable barrier comprising:
disposing a plurality of conductive members on an edge of a moveable barrier, wherein the edge has a width and each of the conductive members is disposed along a portion of the width; and
determining whether an obstruction exists within a path of movement of the barrier by analyzing a first capacitance sensed by a first of the plurality of conductive members and ground and a second capacitance sensed by a second of the plurality of conductive members and ground.

20. The method of claim 19 comprising determining whether damage exists by analyzing the first and second capacitances.

21. The method of claim 19 comprising determining a relationship between the first capacitance and the second capacitance and wherein determining whether the obstruction exists comprises determining whether the obstruction exists based upon the first capacitance, the second capacitance, and the relationship.

22. The method of claim 21 comprising determining whether one of the plurality of conductive members is damaged based upon analyzing the first capacitance, the second capacitance, and the relationship.

23. The method of claim 21 comprising determining a sensitivity to an obstruction by analyzing the average capacitance sensed by of at least two of the plurality of conductive members and ground.

24. The method of claim 23 comprising updating the sensitivity periodically.

25. The method of claim 21 comprising creating a map of sensed capacitances versus positions of the barrier and storing the map in memory.

26. A method for determining whether damage exists to conductive members disposed on a moveable barrier comprising:
positioning a plurality of conductive members on an edge of a moveable barrier, wherein the edge has a width and each of the conductive members is disposed along a portion of the width; and
determining whether damage exists to one of the conductive members by analyzing a first capacitance sensed by a first of the plurality of conductive members and ground and a second capacitance sensed between a second of the plurality of members and ground.

27. The method of claim 26 further comprising determining a relationship between the first capacitance and the second capacitance and wherein determining whether damage exists comprises determining whether damage exists based upon the first capacitance, the second capacitance, and the relationship.

28. The method of claim 26 comprising determining a sensitivity to an obstruction by analyzing the average capacitance sensed by of at least two of the plurality of conductive members and ground.

29. The method of claim 28 comprising updating the sensitivity periodically.

30. The method of claim 26 comprising creating a map of sensed capacitances versus positions of the barrier and storing the map in memory.
